(19) United States
(12) Patent Application Publication
(10) Pub. No.: US 2013/0200382 A1
(43) Pub. Date: Aug. 8, 2013

(54) THIN-FILM TRANSISTOR SUBSTRATE AND METHOD OF MANUFACTURING A THIN-FILM TRANSISTOR SUBSTRATE

(71) Applicant: SAMSUNG DISPLAY CO., LTD., Yongin-City (KR)

(72) Inventors: Byeong-Beom KIM, Asan-si (KR); Joon-Yong PARK, Gunpo-si (KR); Sang-Won SHIN, Yongin-si (KR); Chang-Oh JEONG, Suwon-si (KR)

(73) Assignee: SAMSUNG DISPLAY CO., LTD., Yongin-City (KR)

(21) Appl. No.: 13/717,795

(22) Filed: Dec. 18, 2012

(30) Foreign Application Priority Data
Feb. 2, 2012 (KR) 10-2012-0010755

(51) Int. Cl. H01L 29/45; H01L 21/8232; H01L 27/15

(52) U.S. Cl. CPC H01L 29/45; H01L 27/15; H01L 21/8232
USPC 257/59; 438/34

(57) ABSTRACT

In a thin-film transistor (“TFT”) substrate and a method of manufacturing a TFT substrate, the TFT substrate includes a base substrate, a gate pattern, a source pattern and a pixel electrode. One of the gate pattern and the source pattern includes a pure copper layer, and a conductive layer under the pure copper layer. The conductive layer includes a copper alloy oxide, a copper alloy nitride or a copper alloy oxynitride.

This application claims priority to Korean Patent Application No. 10-2012-0010755, filed on Feb. 2, 2012, and all the benefits accruing therefrom under 35 U.S.C. § 119, the contents of which are herein incorporated by reference in its entirety.

### BACKGROUND

1. Field

Exemplary embodiments of the invention relate to a thin-film transistor (“TFT”) substrate and a method of manufacturing a TFT substrate. More particularly, exemplary embodiments of the invention relate to a TFT substrate improving a display quality and a manufacturing reliability, and a method of manufacturing a TFT substrate.

2. Description of the Related Art

As a size of a display device and a requirement of a customer for a high resolution are increased, a length of signal lines in the display device is increased while a width of the signal lines is decreased, so that an electrical resistance is increased. The increased electrical resistance causes a resistance-capacitance (“RC”) signal delay in the display device. The signal lines include a metal having a relatively low resistance or have an increased thickness, in order to reduce the RC signal delay.

The signal lines may include copper as the metal having the relatively low resistance and for example, may be used in forming a gate line or a data line of the display device. Copper has excellent electrical conductivity and is in relatively abundant supply as a natural resource. In addition, copper has a resistance much lower than aluminum or chrome.

However, an adhesive strength between a pure copper layer and a glass substrate is low and the pure copper layer may react with an insulating layer under the pure copper layer, such that the copper layer may be undesirably damaged.

To improve the adhesive strength of the copper relative to other layers and to reduce damage to the pure copper layer, a titanium layer is disposed under the pure copper layer as a barrier layer between the pure copper layer and, for example, a lower layer. However, the lower layer which is under the titanium barrier layer or the glass substrate which is under the barrier layer may be easily damaged in a process for pattering the titanium barrier layer. In addition, when the titanium barrier layer is directly on a semiconductive layer, chemical properties of the semiconductive layer may be undesirably changed by the titanium layer.

A copper alloy layer as an alternative barrier layer to the titanium barrier layer has been explored. When the copper alloy layer serves as the barrier layer, a damage of the glass substrate or the lower layer may be minimized However, improvement of the adhesive strength of the pure copper layer is limited. In addition, alloy components of the copper alloy layer may undesirably penetrate to the pure copper layer, so that the copper alloy barrier layer is insufficient as the barrier layer for the pure copper layer.

### SUMMARY

One or more exemplary embodiments of the invention provide a thin-film transistor

(“TFT”) substrate capable of improving an adhesive strength of a pure copper layer with a glass substrate or with an insulting layer, and minimizing a damage of the glass substrate, the insulating layer or the pure copper layer.

One or more exemplary embodiments of the invention also provide a method of manufacturing a TFT substrate capable of improving a manufacturing reliability and productivity.

According to an embodiment of the invention, a TFT substrate includes a base substrate, a gate pattern, a source pattern and a pixel electrode. The gate pattern is on the base substrate and includes a gate line, and a gate electrode which is connected to the gate line. The source pattern includes a data line which crosses the gate line, a source electrode which is connected to the data line, and a drain electrode which is spaced apart from the source electrode. The pixel electrode contacts the drain electrode. The gate pattern or the source pattern includes a pure copper layer, and a conductive layer under the pure copper layer. The conductive layer includes a copper alloy oxide, a copper alloy nitride or a copper alloy oxynitride.

In an embodiment, the conductive layer may include at least one selected from vanadium (V), titanium (Ti), zirconium (Zr), aluminum (Al), tantalum (Ta), manganese (Mn), magnesium (Mg), chrome (Cr), molybdenum (Mo), cobalt (Co), nickel (Ni), tin (Sn), tungsten (W), niobium (Nb) and neodymium (Nd).

In an embodiment, the TFT substrate may further include a semiconductive pattern disposed on the gate electrode. The semiconductive pattern may overlap the source electrode and the drain electrode, and may include an oxide semiconductor.

According to an embodiment of the invention, a TFT substrate includes a base substrate, a gate pattern, a source pattern and a pixel electrode. The gate pattern is on the base substrate and includes a gate line, and a gate electrode which is connected to the gate line. The source pattern includes a data line which crosses the gate line, a source electrode which is connected to the source electrode, and a drain electrode which is spaced apart from the source electrode. The pixel electrode contacts the drain electrode. The gate pattern or the source pattern includes a pure copper layer, and a conductive layer under the pure copper layer, and the conductive layer includes a zinc alloy oxide or an indium alloy oxide.

In an embodiment, the conductive layer may include at least one selected from indium (In), lithium (Li), sodium (Na), magnesium (Mg), potassium (K), calcium (Ca), scandium (Sc), yttrium (Y), titanium (Ti), hafnium (Hf), strontium (Sr), zirconium (Zr), barium (Ba), lanthanum (La), cobalt (Co), copper (Cu), cadmium (Cd), boron (B), aluminum (Al), thallium (Tl), germanium (Ge), silicon (Si), tin (Sn), lead (Pb), antimony (Sb), bismuth (Bi), fluorine (F), chlorine (Cl), praseodymium (Pr) and neodymium (Nd), with indium and/or zinc.

According to another embodiment of the invention, a method of manufacturing a TFT substrate is provided. In the method, a gate pattern is formed on a base substrate, and the gate pattern includes a gate line, and a gate electrode which is connected to the gate line. A source pattern is formed, and the source pattern includes a data line which crosses the gate line, a source electrode which is connected to the data line and a drain electrode which is spaced apart from the source electrode. A pixel electrode is formed, and the pixel electrode contacts the drain electrode. Forming the gate pattern or the source pattern includes forming a pure copper layer, forming a conductive layer on the pure copper layer, and patterning the pure copper layer and the conductive layer. The conductive layer includes a copper alloy oxide, a copper alloy nitride or a copper alloy oxynitride.

In an embodiment, the conductive layer may be formed by sputtering copper and an alloy element with a reactive gas on the base substrate including the pure copper layer. The reactive gas includes oxygen or nitrogen.

In an embodiment, the alloy element may include at least one selected from vanadium (V), titanium (Ti), zirconium (Zr), aluminum (Al), tantalum (Ta), manganese (Mn), magnesium (Mg), chrome (Cr), molybdenum (Mo), cobalt (Co), nickel (Ni), tin (Sn), tungsten (W), niobium (Nb) and neodymium (Nd).

In an embodiment, the conductive layer may be formed by forming a copper alloy layer on the base substrate including the pure copper layer, and providing a reactive gas to the copper alloy layer. The reactive gas includes oxygen or nitrogen.

In an embodiment, the forming the gate pattern or the source pattern includes etching the conductive layer and the pure copper layer using an etching composition. The etching composition may include a phosphoric acid based compound, an acetic acid based compound or a nitric acid based compound.

According to one or more embodiments of the invention, a barrier layer to a pure copper layer is formed using a conductive layer including a copper alloy oxide, a copper alloy nitride or a copper alloy oxynitride or including an indium alloy oxide or a zinc alloy oxide, to improve an adhesive strength of the pure copper layer with respect to a glass substrate or an insulating layer. Components of the conductive layer as impurities may not penetrate to the pure copper layer in a thermal process, and an increase of a resistance of the pure copper layer is reduced or effectively prevented by the conductive layer. In addition, although a method of forming the TFT substrate may include performing a hydrogen plasma process, the conductive layer may reduce or effectively prevent a blister from being formed in the pure copper layer.

Furthermore, although a component for etching the conductive layer is not added in a non-peroxide based etchant including a phosphoric acid based compound, an acetic acid based compound or a nitric acid based compound, the conductive layer may be easily etched with the pure copper layer using the non-peroxide based etchant. The components of the non-peroxide based etchant may be essentially unchanged in etching the conductive layer and the pure copper layer, such that an etching ability of the non-peroxide based etchant is improved. In addition, since the non-peroxide based etchant does not include a component etching the conductive layer, a decrease in the etching ability of the non-peroxide based etchant by the component etching the conductive layer may be reduced or effectively prevented.

Therefore, a TFT substrate may include a low-resistance line such as a gate line and/or a data line including a pure copper layer stably formed by the conductive layer, so that a resistance-capacitance (“RC”) delay may be sufficiently addressed to improve a display quality of a display device including the TFT substrate. Simultaneously, a manufacturing reliability and a productivity of the TFT substrate may be improved.

### BRIEF DESCRIPTION OF THE DRAWINGS

The above and other features and advantages of the invention will become more apparent by describing in detailed exemplary embodiments thereof with reference to the accompanying drawings, in which:

FIG. 1 is a plan view illustrating an exemplary embodiment of a thin film transistor (“TFT”) substrate according to the invention;

FIG. 2 is a cross-sectional view taken along line I-I′ in FIG. 1;

FIG. 3A to FIG. 3C are cross-sectional views illustrating an exemplary embodiment of a method of manufacturing the TFT substrate in FIG. 1 and FIG. 2;

FIG. 4 is a cross-sectional view illustrating another exemplary embodiment of a TFT substrate according to the invention; and

FIG. 5 is a cross-sectional view illustrating still another exemplary embodiment of a TFT substrate according to the invention.

### DETAILED DESCRIPTION

It will be understood that when an element or layer is referred to as being “on” or “connected to” another element or layer, the element or layer can be directly on or connected another element or layer or intervening elements or layers. In contrast, when an element is referred to as being “directly on” or “directly connected to” another element or layer, there are no intervening elements or layers present. As used herein, connected may refer to elements being physically and/or electrically connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “under” relative to other elements or features would then be oriented “upper” or “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be explained in detail with reference to the accompanying drawings.

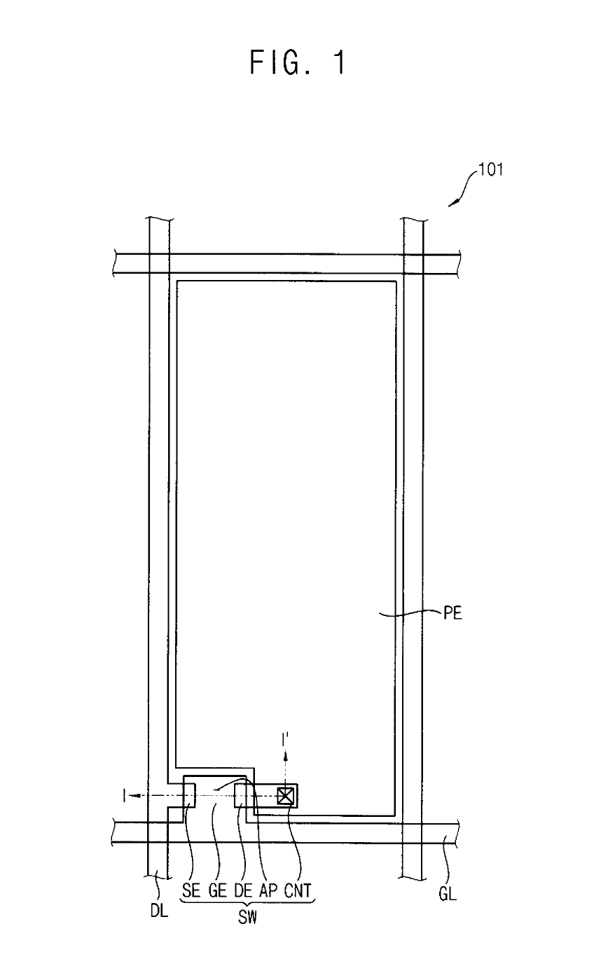

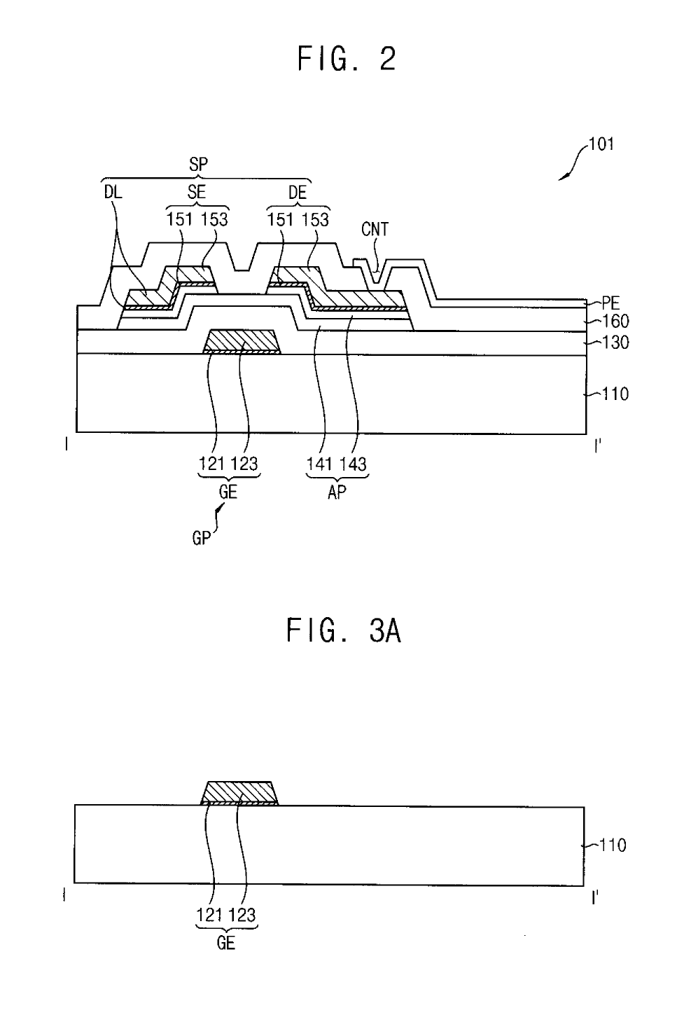

FIG. 1 is a plan view illustrating an exemplary embodiment of a thin film transistor (“TFT”) substrate according to the invention, and FIG. 2 is a cross-sectional view taken along line I-I′ in FIG. 1.

Referring to FIG. 1 and FIG. 2, a TFT substrate 101 includes a gate line GL, a data line DL crossing the gate line GL, a TFT SW as a switching element and a pixel electrode PE. The TFT SW is connected to the gate line GL and the data line DL, and the pixel electrode PE is connected to the TFT SW through a contact hole CNT.

Hereinafter, a pattern including the same metal layer and/or being in the same metal layer as the gate line GL, and formed with the gate line GL in a process of forming the gate line GL, is referred to a “gate pattern GP.” The gate line GL may also be a gate pattern GP. Components and/or layers included in one gate pattern GP substantially have the same stacking structure as another gate pattern GP. In addition, a pattern including the same metal layer and/or being in the same met layer as the data line DL, and formed with the data line DL in a process of forming the data line DL, is referred to a “source pattern SP.” The data line DL may also be a source pattern SP. Components and/or layers included in on source pattern SP substantially have the same stacking structure as another source pattern SP.

When viewed in a cross-section, the TFT substrate 101 further includes a first insulating layer 130 on the gate pattern GP, a semiconductive pattern AP of the TFT SW, and a second insulating layer 160 on the source pattern SP.

The gate pattern GP is on a base substrate 110 and includes the gate line GL, and a gate electrode GE of the TFT SW connected to the gate line GL. Although the stacking structure of the gate electrode GE is shown in FIG. 2, the stacking structure of the gate line GL is substantially the same as the gate electrode GE.

The gate pattern GP includes a first conductive layer 121, and a first pure copper layer 123 on the first conductive layer 121. The first pure copper layer 123 is defined as a copper layer including only copper or including traces of impurities to have purity greater than about 95%. The first pure copper layer 123 has a low adhesive strength with the base substrate 110 and may be easily delaminated from the base substrate 110. However, when the first conductive layer 121 is on the base substrate 110, the first conductive layer 121 may directly contact the base substrate 110 and is disposed between the base substrate 110 and the first pure copper layer 123. Thus, the first conductive layer 121 may strengthen the adhesive strength between the first pure copper layer 123 and the base substrate 110.

In one exemplary embodiment, for example, the first conductive layer 121 includes a copper alloy oxide, a copper alloy nitride or a copper alloy oxynitride. The first conductive layer 121 includes at least one alloy element with copper. That is, the first conductive layer 121 includes an oxide, a nitride or an oxynitride of a multiple alloy including two alloy elements.

The alloy elements may include one selected from vanadium (V), titanium (Ti), zirconium (Zr), aluminum (Al), tantalum (Ta), manganese (Mn), magnesium (Mg), chrome

(Cr), molybdenum (Mo), cobalt (Co), nickel (Ni), tin (Sn), tungsten (W), niobium (Nb), neodymium (Nd), etc. These may be used alone or a combination thereof Exemplary embodiments of the first conductive layer 121 may include copper magnesium aluminum oxide (CuMgAlOₓ, 0<x<1), copper manganese oxide (CuMnOₓ, 0<x<1), etc.

When the first conductive layer 121 includes a copper alloy having a better adhesion than copper or a copper oxide with the base substrate 110, an alloy element easily reacts with oxygen, compared to copper, in manufacturing the TFT substrate 101. Thus, it may be difficult to improve an adhesive strength of the first pure copper layer 123. In addition, the alloy element of the copper alloy is diffused to the first pure copper layer 123 so that the chemical and/or mechanical properties of the first pure copper layer 123 may be easily changed. In contrast, one or more exemplary embodiments of the first conductive layer 121 according to the invention may improve the adhesive strength of the first pure copper layer 123, and damage to the first pure copper layer 123 by the first conductive layer 121 is fundamentally reduced or prevented. In addition, although manufacturing the TFT substrate 101 may include performing a hydrogen plasma process to the first pure copper layer 123, the first conductive layer 121 may reduce or effectively prevent a blister from being formed in the first pure copper layer 123.

The first pure copper layer 123 may have a thickness in a range of about 1,000 angstroms (Å) to several micrometers (μm). When the thickness of the first pure copper layer 123 is increased, a resistance of the gate line GL is decreased such that the gate line GL is a low-resistance signal line. When a thickness of the first conductive layer 121 is larger than about 1/10 of the thickness of the first pure copper layer 123, a process time for forming the first conductive layer 121 is increased, and the first conductive layer 121 may interrupt decreasing the resistance of the gate line GL. In addition, when the thickness of the first conductive layer 121 is less than about 1/10 of the thickness of the first pure copper layer 123, the first pure copper layer 123 may be easily detached from the base substrate 110 although the first conductive layer 121 is between the pure copper layer 123 and the base substrate 110. Therefore, in an exemplary embodiment, the thickness of the first conductive layer 121 may be about 1/10 of the thickness of the first pure copper layer 123.

The first insulating layer 130 may cover (e.g., overlap) an entire of the base substrate which includes the gate pattern GP thereon. The first insulating layer 130 may include silicon nitride and/or silicon oxide.

The source pattern SP includes the data line DL, a source electrode SE of the TFT SW connected to the data line DL, and a drain electrode DE of the TFT SW spaced apart from the source electrode SE.

The source pattern SP includes a second conductive layer 151 contacting the semiconductive pattern AP and a second pure copper layer 153 on the second conductive layer 151. The second conductive layer 151 may improve an adhesive strength between the semiconductive pattern AP and the second pure copper layer 153. The second conductive layer 151 may reduce or effectively prevent a change in the chemical and/or mechanical properties of the second pure copper layer 153 or the semiconductive pattern AP by contacting the second pure copper layer 153 and the semiconductive pattern AP. The second conductive layer 151 may include substantially the same material as the first conductive layer 121, and thus any repetitive descriptions of the material of the second conductive layer 151 will be omitted.

The semiconductive pattern AP is on the first insulating layer 130 at a region including the gate electrode GE. Portions of the semiconductive pattern AP overlap the gate electrode GE, and with the source electrode SE and the drain electrode DE. The semiconductive pattern AP is disposed between the gate electrode GE and the source electrode SE and between the gate electrode GE and the drain electrode DE.

The semiconductive pattern AP may include a semiconductive layer 141, and an ohmic contact layer 143 on the semiconductive layer 141. The semiconductive layer 141 may include a semiconductive material, for example, amorphous silicon. The ohmic contact layer 143 of the semiconductive pattern AP is disposed between the semiconductive layer 141 and the source electrode SE and between the semiconductive layer 141 and the drain electrode DE. The ohmic contact layer 143 may include amorphous silicon into which n⁺ impurities are implanted at a high concentration.

Although not shown in figures, a dummy pattern substantially having the same stacking structure as the semiconductive pattern AP may be between the data line DL and the first insulating layer 130.

The second insulating layer 160 covers the source pattern SP and includes the contact hole CNT which extends through a thickness of the second insulating layer 160 and partially exposes the drain electrode DE. The second insulating layer 160 may include silicon nitride and/or silicon oxide.

Although not shown in figures, an organic layer may be between the second insulating layer 160 and the pixel electrode PE. The organic layer may planarize a surface of the TFT substrate 101. Where the organic layer is between the second insulating layer 160 and the pixel electrode PE, the contact hole CNT passes through thicknesses of both the second insulating layer 160 and the organic layer, to expose a portion of the drain electrode DE.

The pixel electrode PE is on the second insulating layer 160 and contacts the drain electrode DE through the contact hole CNT. Thus, the pixel electrode PE is connected to the TFT SW, the gate line GL and the data line DL. The pixel electrode PE may include indium zinc oxide (“IZO”) or indium tin oxide (“ITO”).

According to one or more embodiments of the invention, since the gate pattern GP and/or the source pattern SP may have the above described double-layered structure, respectively, an adhesive strength is improved between a pure copper layer of the pattern and the base substrate 110, the semiconductive pattern AP and/or the first insulating layer 130 which are disposed under the pure copper layer. In particular, the first and second conductive layers 121 and 151 are used as a barrier layer of the double-layered structure of the pattern, so that a change in the properties of the first and second pure copper layers 123 and 153 or the semiconductive pattern AP may be reduced or effectively prevented.

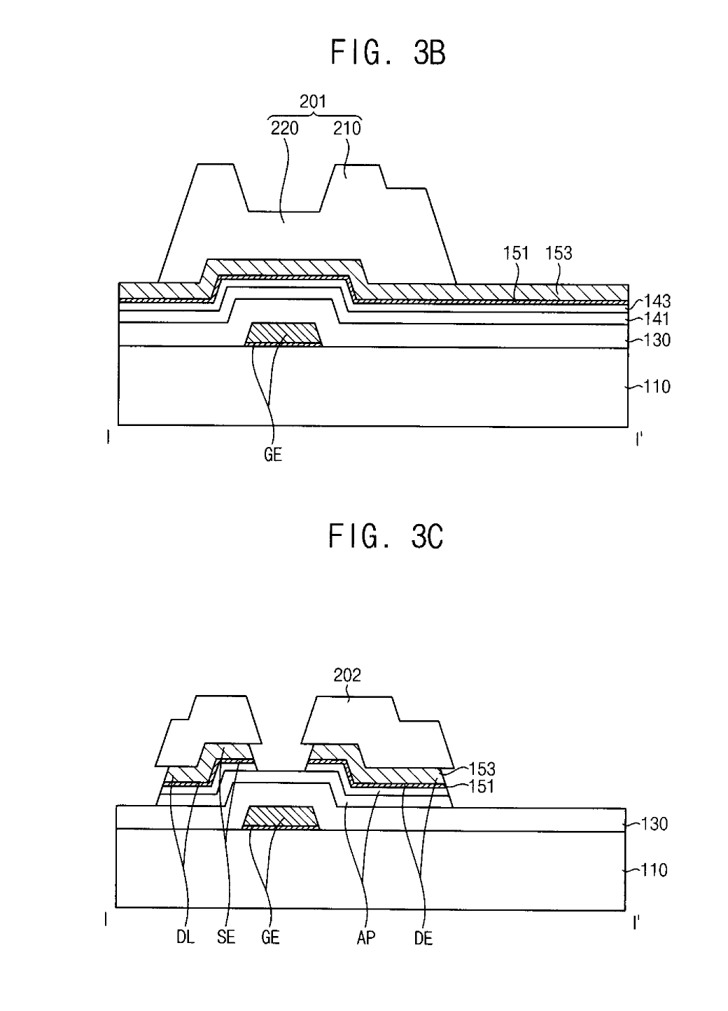

Hereinafter, referring to FIG. 3A to FIG. 3C, a method of manufacturing the TFT substrate 101 shown in FIG. 1 and FIG. 2 will be illustrated.

FIG. 3A to FIG. 3C are cross-sectional views illustrating an exemplary embodiment of a method of manufacturing the TFT substrate 101 in FIG. 1 and FIG. 2.

Referring to FIG. 3A with FIG. 1, the gate pattern GP including the gate electrode GE is formed on the base substrate 110.

Firstly, the first conductive layer 121 is formed on the base substrate 110, and the first pure copper layer 123 is formed on the base substrate 110 which includes the first conductive layer 121. Then, the first conductive layer 121 and the first pure copper layer 123 are patterned such as by a photolithography process to form the gate pattern GP.

The first conductive layer 121 may be formed on the base substrate 110 by sputtering copper and an alloy element with a reactive gas. The reactive gas may include oxygen (O₂) and/or nitrogen (N₂).

In one exemplary embodiment, for example, when oxygen as the reactive gas is used, a copper alloy oxide is generated to form the first conductive layer 121. Alternatively, when nitrogen as the reactive gas is used, a copper alloy nitride is generated to form the first conductive layer 121. In addition, when both of oxygen and nitrogen as the reactive gas are used, the copper alloy oxynitride may be generated.

Alternatively, after a copper alloy layer is formed on the base substrate 110, a plasma treatment is performed on the copper alloy layer using the reactive gas to form the first conductive layer 121. Oxygen and/or nitrogen are provided to the copper alloy layer to form the first conductive layer 121 including the copper alloy oxide, the copper alloy nitride or the copper alloy oxynitride.

The first conductive layer 121 and the first pure copper layer 123 may be etched in whole using a single etching composition in the photolithography process. In one exemplary embodiment, for example, the first conductive layer 121 and the first pure copper layer 123 may be etched using a non-peroxide based etchant including a phosphoric acid based compound, an acetic acid based compound or a nitric acid based compound, generally used in etching a copper layer.

When a titanium layer is used as a barrier layer to the first pure copper layer 123 in a pattern being formed, an etchant including components different from an etchant etching the first pure copper layer 123, for example, hydrofluoric acid (HF), are required to etch the titanium layer. In using the etchant with the different components as the etchant for the first pure copper layer 123, the base substrate 110 may be easily damaged by hydrofluoric acid in etching the titanium layer. However, in an exemplary embodiment of the invention, the first conductive layer 121 may be etched using the non-peroxide based etchant with the first pure copper layer 123 to improve productivity and a reliability of an etching process.

Further, when the etchant includes hydrofluoric acid, fluorine ions are continuously generated in etching the titanium layer so that an amount of the fluorine ions is increased. Thus, the fluorine ions need to be removed such as in an additional process or an etching ability of the hydrofluoric acid is reduced. In contrast, when the first conductive layer 121 and the first pure copper layer 123 are etched using the non-peroxide based etchant, the change of components of the non-peroxide based etchant is little so that an etching ability of the non-peroxide based etchant may be relatively improved.

Referring to FIG. 3B, the first insulating layer 130, the semiconductive layer 141, the ohmic contact layer 143, the second conductive layer 151, the second pure copper layer 153 and a photo pattern 201 are successively formed on the base substrate 110 which includes the gate pattern GP.

Each of the first insulating layer 130, the semiconductive layer 141, the ohmic contact layer 143, the second conductive layer 151 and the second pure copper layer 153 is formed on an entire of the base substrate 110. The first insulating layer 130, the semiconductive layer 141 and the ohmic contact layer 143 may be formed such as by a chemical vapor deposition process, respectively.

The second conductive layer 151 is formed via substantially the same as a process of forming the first conductive layer 121 except for being formed on the ohmic contact layer 143. Thus, any repetitive descriptions will be omitted. The second pure copper layer 153 may be formed on the base substrate 110 including the second conductive layer 151 such as by a sputtering process.

The photo pattern 201 is formed in a forming region of the source pattern SP and a spaced region between the source electrode SE and the drain electrode DE. In one exemplary embodiment, for example, the photo pattern 201 is formed in forming regions of the data line DL, the source electrode SE and the drain electrode DE shown in FIG. 1 and FIG. 2, and the spaced region. The photo pattern 201 includes a first thickness portion 210 formed in the forming region of the source pattern SP and a second thickness portion 220 formed in the spaced region. The second thickness portion 220 has a smaller thickness than the first thickness portion 210, the thicknesses taken perpendicular to the base substrate 110.

The second pure copper layer 153, the second conductive layer 151, the ohmic contact layer 143 and the semiconductive layer 141 are firstly etched using the photo pattern 201 as an etching stop layer. The second pure copper layer 153 and the second conductive layer 151 may be etched in whole using a non-peroxide based etchant including a phosphoric acid based compound, an acetic acid based compound or a nitric acid based compound. Here, the data line DL and a metal pattern connected to the data line DL are formed. The metal pattern is disposed in the forming regions of the source electrode SE and the drain electrode DE and in the spaced region. A dummy pattern is formed under the data line DL, where the patterned semiconductive layer 141 and ohmic contact layer 143 may remain under the metal pattern.

Referring to FIG. 3C, after the photo pattern 201 is used as a mask, a portion of the photo pattern 201 is removed such as by an ashing process, to form a residual pattern 202. The residual pattern 202 is formed by removing the second thickness portion 220 from the photo pattern 201. Thus, the second pure copper layer 153 disposed in the spaced region may be exposed through the residual pattern 202.

Then, the second pure layer 153 and the second conductive layer 151 are secondly etched using the residual pattern 202 as an etching stop layer to remove the metal pattern disposed in the spaced region. Thus, the source electrode SE connected to the data line DL is formed, and the drain electrode DE spaced apart from the source electrode SE is formed, thereby forming the source pattern SP.

The ohmic contact layer 143 in the spaced region is partially removed using the source pattern SP as an etching stop layer to form the active pattern AP.

Referring again to FIG. 1 and FIG. 2, after removing the residual pattern 202, the second insulating layer 160 is formed on the base substrate 110 including the source pattern SP. The second insulating layer 160 is patterned to form the contact hole CNT.

The pixel electrode PE is formed on the second insulating layer 160 including the contact hole CNT.

Therefore, the TFT substrate 101 shown in FIG. 1 and FIG. 2 is manufactured.

According to the above descriptions, the first conductive layer 121 may improve an adhesive strength between the gate pattern GP and the base substrate 110 and reduce or effectively prevent a change in properties of the first pure copper layer 123. In addition, the second conductive layer 151 may improve an adhesive strength between the source pattern SP and the semiconductive pattern AP and reduce or effectively prevent a change in properties of the second pure copper layer 153 and/or the semiconductive pattern AP. In particular, the gate pattern GP and the source pattern SP are formed using a single etching composition to improve productivity and a reliability of a manufacturing process.

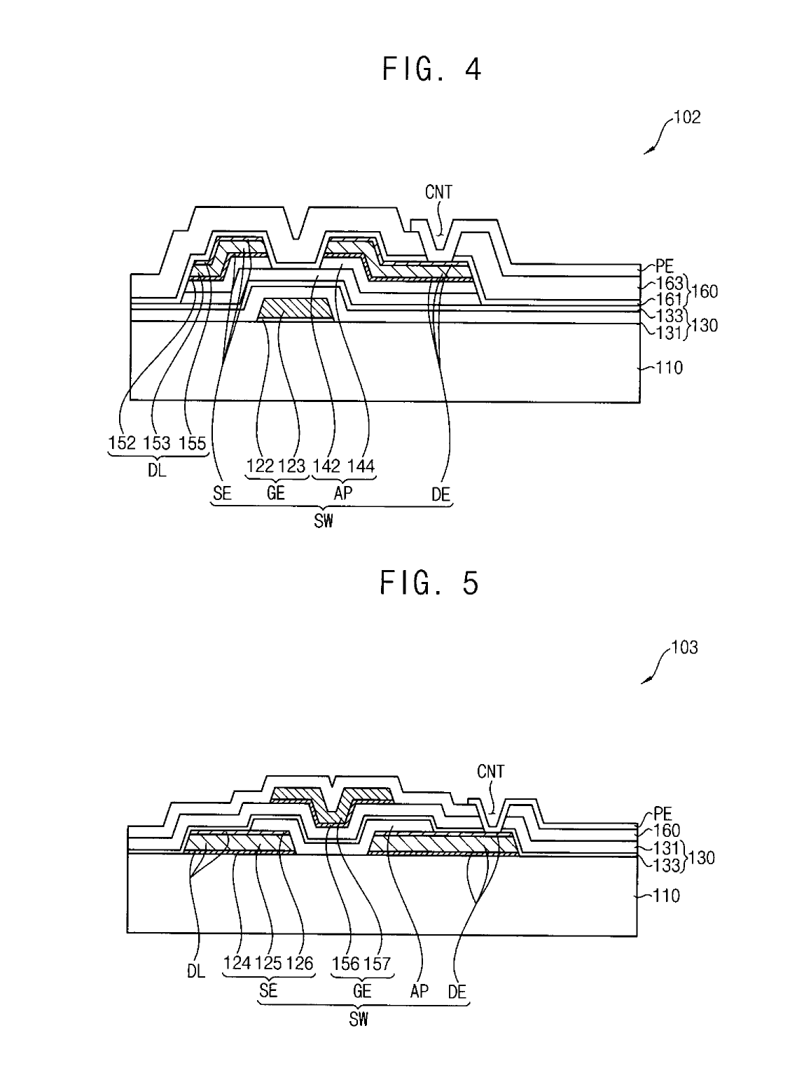

FIG. 4 is a cross-sectional view illustrating another exemplary embodiment of a TFT substrate according to the invention.

A plan view of a TFT substrate 102 shown in FIG. 4 is substantially the same as FIG. 1. Thus, the TFT substrate 102 will be illustrated referring to FIG. 1 and FIG. 4, and any repetitive descriptions will be omitted with the TFT substrate 101 shown in FIG. 1 and FIG. 2.

Referring to FIG. 4 with FIG. 1, the TFT substrate 102 includes a gate pattern GP including a gate line GL, a first insulating layer 130, a semiconductive pattern AP, a source pattern SP including a data line DL, a second insulating layer 160 and a pixel electrode PE.

The gate pattern GP includes a gate electrode GE of a TFT SW connected to the gate line GL. The gate electrode GE may protrude from and be continuous with the gate line GL. The gate line GL and the gate electrode GE include a first conductive layer 122, and a first pure copper layer 123 on the first conductive layer 122, respectively.

The first conductive layer 122 may include a zinc alloy oxide or an indium alloy oxide. The first conductive layer 122 may include an alloy element with zinc and/or indium. The first conductive layer 122 may include a multiple alloy oxide including two alloy elements.

The alloy element may include one selected from lithium (Li), sodium (Na), magnesium (Mg), potassium (K), calcium (Ca), scandium (Sc), yttrium (Y), titanium (Ti), hafnium (Hf), strontium (Sr), zirconium (Zr), barium (Ba), lanthanum (La), cobalt (Co), copper (Cu), cadmium (Cd), boron (B), aluminum (Al), thallium (Tl), germanium (Ge), silicon (Si), tin (Sn), lead (Pb), antimony (Sb), bismuth (Bi), fluorine (F), chlorine (Cl), praseodymium (Pr), neodymium (Nd), etc. These may be used alone or a combination thereof. In one exemplary embodiment, for example, the first conductive layer 122 may include zinc indium oxide (ZnInOₓ, 0<x<1) or zinc indium oxide additionally adding the alloy element.

The first conductive layer 122 may improve an adhesive strength of the first pure copper layer 123, and damage to the first pure copper layer 123 by the first conductive layer 122 may be fundamentally reduced or effectively prevented.

Alternatively, the first conductive layer 122 may be substantially the same as the first conductive layer 121 including the copper alloy oxide, the copper alloy nitride or the copper alloy oxynitride and illustrated in FIG. 2.

The first insulating layer 130 is on the base substrate 110 including the gate pattern GP. The first insulating layer 130 may include a silicon nitride layer 131 directly contacting the base substrate 110, and a silicon oxide layer 133 on the silicon nitride layer 131. The silicon oxide layer 133 may reduce or effectively prevent a change of the properties of the silicon nitride layer 131 due to a reaction with the semiconductive pattern AP. The first insulating layer 130 may have a double layered structure including the silicon nitride layer 131, in order to minimize a forming rate of the first insulating layer 130 or a change of a patterning rate.

The semiconductive pattern AP is on the first insulating layer 130 at a region including the gate electrode GE. The semiconductive pattern AP directly contacts the silicon oxide layer 133, but the invention is not limited thereto or thereby. In one exemplary embodiment, for example, the semiconductive pattern AP may include a semiconductive layer 142 including an oxide semiconductor. The semiconductive layer 142 may include a single metal oxide including a pure metal or a multiple metal oxide including two metals different from each other. In one exemplary embodiment, for example, the semiconductive pattern AP may include gallium indium zinc oxide (GaInZn oxide, “GIZO”). The semiconductive pattern AP may further include an ohmic contact layer 144.

Although not shown in figures, the TFT substrate 102 may include a dummy pattern under the data line DL and having the same stacking structure as the semiconductive pattern AP.

The source pattern SP include a source electrode SE of a TFT SW connected to the data line DL, and a drain electrode DE spaced apart from the source electrode SE. The source electrode SE may protrude from and be continuous with the data line DL. The data line DL, the source electrode SE and the drain electrode DE include a second conductive layer 152 and a second pure copper layer 153, respectively. The second conductive layer 152 contacts the semiconductive pattern AP and includes an indium alloy oxide or a zinc alloy oxide. The second conductive layer 152 is substantially the same as the first conductive layer 122 except for being on the semiconductive pattern AP, and thus any repetitive descriptions will be omitted. The second pure copper layer 153 is on the second conductive layer 152.

The source pattern SP may further include a capping layer 155 on the second pure copper layer 153. The capping layer 155 may reduce or effectively prevent a change in properties of the second pure copper layer 153 by contacting the second insulating layer 160 and the second pure copper layer 153. In one exemplary embodiment, for example, the capping layer 155 may include copper-manganese alloy.

The second insulating layer 160 includes a silicon oxide layer 161 contacting the source pattern SP, and a silicon nitride layer 163 on the silicon oxide layer 161. Since the silicon oxide layer 161 is between the silicon nitride layer 163 and the source pattern SP, the silicon oxide layer 161 may prevent the silicon nitride layer 163 from contacting the source pattern SP so that a change in properties of the source pattern SP may be minimized

The second insulating layer 160 includes a contact hole CNT extending through a thickness thereof and exposing a portion of the drain electrode DE. The pixel electrode PE on the second insulating layer 160 may be connected to the TFT SW through the contact hole CNT.

According to one or more embodiments of the invention, the gate pattern GP and/or the source pattern SP may have the above described double-layered structure, respectively, an adhesive strength is improved between a pure copper layer of the pattern and the base substrate 110 or the semiconductive pattern AP which are disposed under the pure copper layer. In particular, the first and second conductive layers 122 and 152 are used as a barrier layer of the double-layered structure of the pattern, so that a change in the properties of the first and second pure copper layers 123 and 153 or the semiconductive pattern AP may be reduced or effectively prevented.

A method of manufacturing the TFT substrate 102 will be described referring to FIG. 4. The first conductive layer 122 and the first pure copper layer 123 are formed on the base substrate 110, and patterned to form the gate pattern GP. The first conductive layer 122 and the first pure copper layer 123 may be etched in whole using the same etching composition.

The first insulating layer 130 is formed on the base substrate 110 including the gate pattern GP, and the semiconductive pattern AP and the source pattern SP are formed on the first insulating layer 130. A process for forming the semiconductive pattern AP and the source pattern SP is substantially the same as illustrated in FIG. 3B and FIG. 3C except that the source pattern SP further includes the capping layer 155, and thus any repetitive descriptions will be omitted. The semiconductive pattern AP and the source pattern SP may be formed using a different etching composition from each other.

The second insulating layer 160 is formed on the base substrate 110 including the source pattern SP, and the pixel electrode PE contacting the drain electrode DE through the contact hole CNT is formed, thereby manufacturing the TFT substrate 102.

According to the above descriptions, the first conductive layer 122 may improve an adhesive strength between the gate electrode GE of the gate pattern GP and the base substrate 110 and reduce or effectively prevent a change in properties of the first pure copper layer 123. In addition, the second conductive layer 152 may improve an adhesive strength between the source electrode SE and the drain electrode DE of the source pattern SP and the semiconductive pattern AP and reduce or effectively prevent a change in properties of the second pure copper layer 153 and the semiconductive pattern AP. In particular, the gate pattern GP and the source pattern SP are formed using a single etching composition to improve productivity and a reliability of a manufacturing process.

FIG. 5 is a cross-sectional view illustrating another exemplary embodiment of a TFT substrate according to the invention.

A plan view of a TFT substrate 103 shown in FIG. 5 is substantially the same as FIG. 1. Thus, the TFT substrate 103 will be illustrated referring to FIG. 1 and FIG. 5, and any repetitive descriptions will be omitted with the TFT substrate 101 shown in FIG. 1 and FIG. 2.

Referring to FIG. 5 with FIG. 1, the TFT substrate 103 includes a source pattern SP including a data line DL, a semiconductive pattern AP, a first insulating layer 130 on the semiconductive pattern AP, a gate pattern GP including a gate line GL, a second insulating layer 160 and a pixel electrode PE.

The source pattern SP includes the data line DL, a source electrode SE of a TFT SW connected to the data line, and a drain electrode DE spaced apart from the source electrode SE. The data line DL, the source electrode SE and the drain electrode DE includes a first conductive layer 124 and a first pure copper layer 125. The source pattern SP may further include a capping layer 126 on the first pure copper layer 125.

The first conductive layer 124 may include a copper alloy oxide, a copper alloy nitride or a copper alloy oxynitride. Alternatively, the first conductive layer 124 may include an indium alloy oxide or a zinc alloy oxide. Materials of the first conductive layer 124 are repetitive with the first conductive layer 121 and 122 illustrated in FIG. 2 and FIG. 4, and thus any repetitive descriptions will be omitted.

The capping layer 126 may include copper-manganese alloy.

The semiconductive pattern AP may include a silicon based semiconductor or an oxide semiconductor. The semiconductive pattern AP may include an ohmic contact layer (not shown) between a semiconductive layer and the capping layer 126.

The first insulating layer 130 covers the semiconductive pattern AP and partially covers the source pattern SP. The first insulating layer 130 includes a silicon oxide layer 131, and a silicon nitride silicon layer 133 on the silicon oxide layer 131.

The gate pattern GP is on the first insulating layer 130. The gate pattern GP includes a second conductive layer 156, and a second pure copper layer 157 on the second conductive layer 156. The second conductive layer 156 may include a copper alloy oxide, a copper alloy nitride or a copper alloy oxynitride. Alternatively, the second conductive layer 156 may include an indium alloy oxide or a zinc alloy oxide. Materials of the second conductive layer 156 are repetitive with the first conductive layer 121 and 122 illustrated in FIG. 2 and FIG. 4, and thus any repetitive descriptions will be omitted.

The second insulating layer 160 is on the gate pattern GP, and the pixel electrode PE contacts the drain electrode DE via a contact hole CNT passing through thicknesses of both the first and second insulating layers 130 and 160.

A method of manufacturing the TFT substrate 103 will be illustrated referring to FIG. 5. The first conductive layer 124, the first pure copper layer 125 and the capping layer 126 are formed on the base substrate 110 and patterned to form the source pattern SP. A process forming the first conductive layer 124 is substantially the same as a process forming the first conductive layer 121 illustrated in FIG. 3A, and thus any repetitive descriptions will be omitted. The first pure copper layer 125 and the capping layer 126 may be formed by a sputtering process.

The semiconductive pattern AP and the first insulating layer 130 are sequentially formed on the base substrate 110 including the source pattern SP. The second conductive layer 156 and the second pure copper layer 157 are formed on the first insulating layer 130 and are patterned to form the gate pattern GP. A process forming the second conductive layer 156 is substantially the same as a process forming the first conductive layer 121 illustrated in FIG. 3A, and thus any repetitive descriptions will be omitted.

The second insulating layer 160 and the pixel electrode PE are sequentially formed on the base substrate 110 including the gate pattern GP, thereby manufacturing the TFT substrate 103 in FIG. 5.

Although not shown in figures, the semiconductive pattern AP in FIG. 5 may be disposed under the source electrode SE and the drain electrode DE, such as between the base substrate 110 and the source electrode SE and between the base substrate 110 and the drain electrode DE. That is, the semiconductive pattern AP may directly contact the base substrate 110.

According to one or more embodiments of the invention, an adhesive strength of a pure copper layer with respect to a glass substrate or an insulating layer may be improved. In addition, a conductive layer under the pure copper layer may minimize damage to the pure copper layer or a semiconductive pattern contacting the conductive layer. Furthermore, the conductive layer may be easily etched with the pure copper layer using a non-peroxide based etchant known as an etchant of the pure copper layer.

Therefore, a TFT substrate may include a low-resistance signal line such as gate line and/or a data line including a pure copper layer stably formed by the conductive layer, so that a resistance-capacitance (“RC”) delay may be sufficiently addressed to improve a display quality of a display device including the TFT substrate. Simultaneously, a manufacturing reliability and a productivity of the TFT substrate may be improved.

The foregoing is illustrative of the invention and is not to be construed as limiting thereof Although a few exemplary embodiments of the invention have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific exemplary embodiments disclosed, and that modifications to the disclosed exemplary embodiments, as well as other exemplary embodiments, are intended to be included within the scope of the appended claims. The invention is defined by the following claims, with equivalents of the claims to be included therein.

What is claimed is:

1. A thin-film transistor substrate comprising:
a base substrate;
a gate pattern on the base substrate and including a gate line, and a gate electrode which is connected to the gate line;
a source pattern including a data line which crosses the gate line, a source electrode which is connected to the data line, and a drain electrode which is spaced apart from the source electrode; and
a pixel electrode which contacts the drain electrode,
wherein the gate pattern or the source pattern comprises a pure copper layer, and a conductive layer under the pure copper layer, and
wherein the conductive layer comprises a copper alloy oxide, a copper alloy nitride or a copper alloy oxynitride.

2. The thin-film transistor substrate of claim 1, wherein the conductive layer comprises at least one selected from vanadium (V), titanium (Ti), zirconium (Zr), aluminum (Al), tantalum (Ta), manganese (Mn), magnesium (Mg), chrome (Cr), molybdenum (Mo), cobalt (Co), nickel (Ni), tin (Sn), tungsten (W), niobium (Nb) and neodymium (Nd).

3. The thin-film transistor substrate of claim 1, further comprising a semiconductive pattern on the gate electrode, wherein the semiconductive pattern overlaps the source electrode and the drain electrode, and includes an oxide semiconductor.

4. The thin-film transistor substrate of claim 3, further comprising:
a first insulating layer between the gate pattern and the semiconductive pattern, wherein the first insulating layer covers the gate pattern; and
a second insulating layer which covers the source pattern, wherein the source pattern is between the semiconductive pattern and the second insulating layer,
wherein the first or second insulating layer comprises:
a silicon oxide layer which contacts the semiconductive pattern; and
a silicon nitride layer which contacts the silicon oxide layer.

5. The thin-film transistor substrate of claim 3, further comprising:
a first insulating layer between the gate pattern and the semiconductive pattern, wherein the first insulating layer covers the source pattern; and
a second insulating layer which covers the gate pattern, wherein the semiconductive pattern is between the source pattern and the second insulating layer,
wherein the first or second insulating layer comprises:
a silicon oxide layer which contacts the semiconductive pattern; and
a silicon nitride layer which contacts the silicon oxide layer.

6. The thin-film transistor substrate of claim 1, wherein the source pattern comprises the pure copper layer and the conductive layer, and the source pattern further comprises a copper alloy layer on the pure copper layer.

7. The thin-film transistor substrate of claim 1, further comprising a semiconductive pattern on the gate electrode, wherein the semiconductive pattern overlaps the source electrode and the drain electrode, and includes silicon semiconductor.

8. The thin-film transistor substrate of claim 1, further comprising a semiconductive pattern which overlaps the gate electrode, the source electrode and the drain electrode,
wherein the source electrode and the drain electrode are between the gate electrode and the base substrate.

9. A thin-film transistor substrate comprising:
a base substrate;
a gate pattern on the base substrate and including a gate line, and a gate electrode which is connected to the gate line;
a source pattern including a data line which crosses the gate line, a source electrode which is connected to the source electrode, and a drain electrode which is spaced apart from the source electrode; and
a pixel electrode which contacts the drain electrode,
wherein the gate pattern or the source pattern comprises a pure copper layer, and a conductive layer under the pure copper layer, and
wherein the conductive layer comprises a zinc alloy oxide or an indium alloy oxide.

10. The thin-film transistor substrate of claim 9, wherein the zinc alloy oxide comprises at least one selected from indium (In), lithium (Li), sodium (Na), magnesium (Mg), potassium (K), calcium (Ca), scandium (Sc), yttrium (Y), titanium (Ti), hafnium (Hf), strontium (Sr), zirconium (Zr), barium (Ba), lanthanum (La), cobalt (Co), copper (Cu), cadmium (Cd), boron (B), aluminum (Al), thallium (Tl), germanium (Ge), silicon (Si), tin (Sn), lead (Pb), antimony (Sb), bismuth (Bi), fluorine (F), chlorine (Cl), praseodymium (Pr) and neodymium (Nd).

11. The thin-film transistor substrate of claim 9, wherein the indium alloy oxide comprises at least one selected from lithium (Li), sodium (Na), magnesium (Mg), potassium (K), calcium (Ca), scandium (Sc), yttrium (Y), titanium (Ti), hafnium (Hf), strontium (Sr), zirconium (Zr), barium (Ba), lanthanum (La), cobalt (Co), copper (Cu), cadmium (Cd), boron (B), aluminum (Al), thallium (Tl), germanium (Ge), silicon (Si), tin (Sn), lead (Pb), antimony (Sb), bismuth (Bi), fluorine (F), chlorine (Cl), praseodymium (Pr) and neodymium (Nd).

12. The thin-film transistor substrate of claim 9, further comprising a semiconductive pattern which overlaps the source electrode and the drain electrode, the semiconductive pattern including an oxide semiconductor or a silicon semiconductor.

13. The thin-film transistor substrate of claim 12, further comprising an insulating layer between the semiconductive pattern and the gate electrode,
wherein the insulating layer comprises a silicon oxide layer which contacts the semiconductive pattern, and a silicon nitride layer which contacts the silicon oxide layer.

14. A method of manufacturing a thin-film transistor substrate, the method comprising:
forming a gate pattern on a base substrate, the gate pattern including a gate line, and a gate electrode which is connected to the gate line;
forming a source pattern including a data line which crosses the gate line, a source electrode which is connected to the data line, and a drain electrode which is spaced apart from the source electrode; and
forming a pixel electrode which contacts the drain electrode,
wherein the forming the gate pattern or the source pattern comprises:
forming a pure copper layer;
forming a conductive layer on the pure copper layer, the conductive layer including a copper alloy oxide, a copper alloy nitride or a copper alloy oxynitride; and
patterning the pure copper layer and the conductive layer.

15. The method of claim 14, wherein the forming the conductive layer comprises:
sputtering copper and an alloy element with a reactive gas on the base substrate including the pure copper layer, the reactive gas including oxygen or nitrogen.

16. The method of claim 15, wherein the alloy element comprises at least one selected from vanadium (V), titanium (Ti), zirconium (Zr), aluminum (Al), tantalum (Ta), manganese (Mn), magnesium (Mg), chrome (Cr), molybdenum (Mo), cobalt (Co), nickel (Ni), tin (Sn), tungsten (W), niobium (Nb) and neodymium (Nd).

17. The method of claim 14, wherein the forming the conductive layer comprises:
forming a copper alloy layer on the base substrate including the pure copper layer; and
providing a reactive gas to the copper alloy layer, the reactive gas including oxygen or nitrogen.

18. The method of claim 14, wherein the forming the gate pattern or the source pattern further comprises etching the conductive layer and the pure copper layer using an etching composition including a phosphoric acid based compound, an acetic acid based compound or a nitric acid based compound.
